(19) United States
(12) Patent Application Publication
(10) Pub. No.: US 2024/0322792 A1
(43) Pub. Date: Sep. 26, 2024

(54) PIEZOELECTRIC THIN FILM FILTER

(71) Applicant: WISOL CO., LTD., Gyeonggi-do (KR)

(72) Inventors: Yong Hun KO, Gyeonggi-do (KR); Tah Joon PARK, Gyeonggi-do (KR); Sang Ik HAN, Gyeonggi-do (KR)

(21) Appl. No.: 18/606,163

(22) Filed: Mar. 15, 2024

(30) Foreign Application Priority Data
Mar. 22, 2023 (KR) 10-2023-0037091

(51) Int. Cl. H03H 9/56; H03H 9/13

(52) U.S. Cl. CPC H03H 9/564; H03H 9/132

(57) ABSTRACT

A piezoelectric thin film filter includes: a substrate comprising a parallel cavity constituting the parallel resonator and a series cavity constituting the series resonator; a parallel lower electrode formed on a parallel substrate portion constituting the parallel resonator in the substrate; a series lower electrode formed on a series substrate portion constituting the series resonator in the substrate; a piezoelectric layer formed on the substrate, the parallel lower electrode, and the series lower electrode; and an upper electrode formed on the piezoelectric layer, wherein the series lower electrode comprises a first series lower electrode formed on a portion where the series cavity is formed in the series substrate portion, and a second series lower electrode formed on a portion where the series cavity is not formed in the series substrate portion, wherein a thickness of the first series lower electrode is less than or equal to a predetermined thickness.

### CROSS-REFERENCE TO RELATED APPLICATION

This application claims priority to Korean Patent Application No. 10-2023-0037091 filed on Mar. 22, 2023 in the Korean Intellectual Property Office, and all the benefits accruing therefrom under 35 U.S.C. 119, the contents of which in its entirety are herein incorporated by reference.

### FIELD

The present invention relates to a piezoelectric thin film filter, and more specifically, to a piezoelectric thin film filter for improving insertion loss.

### BACKGROUND

With the rapid proliferation of wireless devices represented by mobile phones, the demand for small and lightweight resonators and filters composed of the resonators is increasing. For this demand, dielectric filters and surface acoustic wave (SAW) filters have been predominantly used, but recently, filters composed of piezoelectric thin film resonators, which have good characteristics especially in high frequencies and can be downsized and monolithic integrated, are gaining attention.

The piezoelectric thin film resonator is classified into a film bulk acoustic resonator (FBAR) and a solidly mounted resonators (SMR).

The FBAR has a laminated structure consisting of a lower electrode, a piezoelectric layer, and an upper electrode on a substrate. A cavity is formed below the lower electrode at a portion (resonant portion) where the lower electrode and the upper electrode oppose each other across the piezoelectric film. Here, two types of the cavity in the FBAR are known, one is a cavity formed between the lower electrode and the substrate by wet etching a sacrificial layer provided on the surface of the substrate, and the other is a via hole formed in the substrate by wet etching or dry etching. SMR, instead of cavities in FBAR, has an acoustic multilayer film. The acoustic multilayer film is a film that has a film thickness of λ/4 (λ: wavelength of acoustic wave) formed by laminating films having a high acoustic impedance and films having a low acoustic impedance in alternate order.

The piezoelectric thin film resonators are respectively placed in series arm and parallel arm between input and output terminals to configure the filter. The filters operate as band-pass filters when the resonant frequency of the piezoelectric thin film resonator in the series arm and the antiresonant frequency of the piezoelectric thin film resonator (parallel resonator) in the parallel arm substantially coincide with each other.

However, in such piezoelectric thin film filters, the lower electrodes of the series resonator and the parallel resonator may be deposited, and only the electrodes of the series resonator may be etched to a predetermined thickness to separate the resonant frequencies. When synthesizing filters with such resonators, the resistance of the series resonator may increase and the insertion loss within the band area may increase.

### SUMMARY

Aspects of the present invention provide a piezoelectric thin film filter that can improve insertion loss by modifying the layout of a lower electrode of a series resonator of the filter.

In one general aspect, there is provided a piezoelectric thin film filter with a parallel resonator and a series resonator, including a substrate including a parallel cavity constituting the parallel resonator and a series cavity constituting the series resonator; a parallel lower electrode formed on a parallel substrate portion constituting the parallel resonator in the substrate; a series lower electrode formed on a series substrate portion constituting the series resonator in the substrate; a piezoelectric layer formed on the substrate, the parallel lower electrode, and the series lower electrode; and an upper electrode formed on the piezoelectric layer, wherein the series lower electrode includes a first series lower electrode formed on a portion where the series cavity is formed in the series substrate portion, and a second series lower electrode formed on a portion where the series cavity is not formed in the series substrate portion, wherein a thickness of the first series lower electrode is less than or equal to a predetermined thickness compared to a thickness of the second series lower electrode.

The thickness of the first series lower electrode may be less than or equal to ⅔ of the thickness of the second series lower electrode.

The thickness of the second series lower electrode may be the same as a thickness of the parallel lower electrode.

An electrode edge, a part of the first series lower electrode, adjacent to the parallel lower electrode may extend upward to correspond to the thickness of the parallel lower electrode.

The electrode edge may have a width greater than or equal to 1 nm and less than or equal to 10 nm.

An electrode edge, a part of the first series lower electrode, adjacent to the parallel lower electrode may be a predetermined thickness or less compared to the thickness of the parallel lower electrode.

A series electrode boundary surface of the first series lower electrode that forms a boundary with the second series lower electrode may be formed at a position corresponding to a vertical imaginary surface that defines a space of the series cavity.

A series electrode boundary surface of the first series lower electrode that forms a boundary with the second series lower electrode may be formed outward from a vertical imaginary surface that defines a space of the series cavity.

### Effects of the Invention

According to the present invention, a series lower electrode includes a first series lower electrode formed on a portion of the series substrate portion where the series cavity is formed; and a second series lower electrode formed on a portion of the series substrate portion where the series cavity is not formed, wherein the thickness of the first series lower electrode is less than or equal to a predetermined thickness compared to the thickness of the second series lower electrode. As a result, it is possible to separate the resonant frequencies of the series resonator and the parallel resonator while improving the resistance of the series resonator, thereby reducing insertion loss within the band.

### BRIEF DESCRIPTION OF THE DRAWINGS

FIG. 1 is a conceptual diagram for describing a piezoelectric thin film filter according to the present invention.

FIG. 2 shows a plan view and cross-sectional view of an embodiment of the piezoelectric thin film filter shown in FIG. 1.

FIG. 3 shows a plan view and cross-sectional view of another embodiment of the piezoelectric thin film filter shown in FIG. 1.

FIG. 4 shows a plan view and cross-sectional view of yet another embodiment of the piezoelectric thin film filter shown in FIG. 1.

### DETAILED DESCRIPTION

Hereinafter, exemplary embodiments of the present invention will be described in detail with reference to the accompanying drawings.

The embodiments of the present invention are provided to more completely explain the present invention to one of ordinary skill in the art. The embodiments of the present invention may be changed in a variety of shapes, and the scope of the present invention is not limited to the following embodiments. Rather, these embodiments are provided to make the present disclosure more substantial and complete and to completely transfer the concept of the present invention to those skilled in the art.

The terms used herein are to explain particular embodiments and not intended to limit the present invention. As used herein, singular forms may include plural forms unless particularly defined otherwise in context. Also, as used herein, the term “and/or” includes any and all combinations or one of a plurality of associated listed items. In addition, hereinafter, the embodiments of the present invention will be described with reference to the drawings which schematically illustrate the embodiments of the present invention.

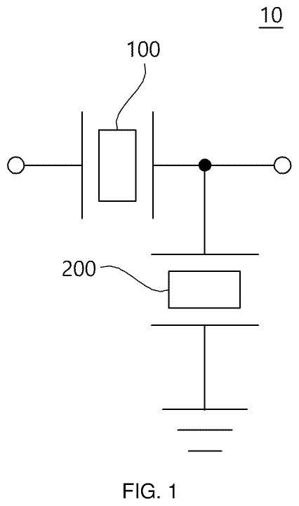

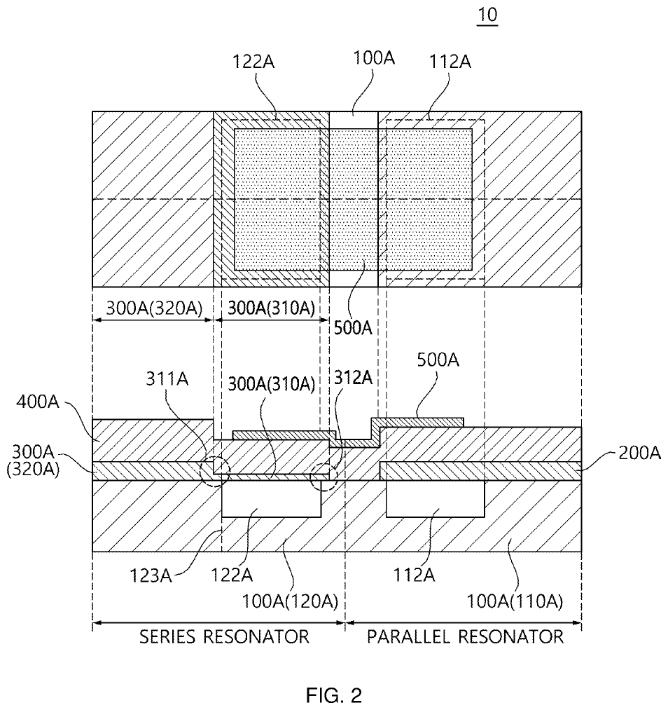

FIG. 1 is a conceptual diagram for describing a piezoelectric thin film filter 10 according to the present invention, and FIG. 2 shows a plan view and cross-sectional view of an embodiment of the piezoelectric thin film filter 10 shown in FIG. 1.

Referring to FIG. 2, the piezoelectric thin film filter 10 includes a substrate 100A, a parallel lower electrode 200A, a series lower electrode 300A, a piezoelectric layer 400A, and an upper electrode 500A. Components of the piezoelectric thin film filter 10 may be classified into a series resonator and a parallel resonator.

As shown in FIG. 2, the parallel resonator includes a parallel substrate portion 110A which is a part of the substrate, a parallel lower electrode 200A, a part of the piezoelectric layer 400A, and a part of the upper electrode 500A, and the series resonator includes a series substrate portion 120A which is the other part of the substrate, a series lower electrode 300A, the other part of the piezoelectric layer 400A, and the other part of the upper electrode 500A.

When a signal is applied externally between the parallel lower electrode 200A and the upper electrode 500A of the parallel resonator, part of the electrical energy transmitted between the two electrodes is converted into mechanical energy due to piezoelectric effect, resonating at the frequency of the inherent vibration depending on the thickness of the piezoelectric layer 400A during the process of converting the mechanical energy back into electrical energy. Similarly, in the case of the series resonator, when a signal is applied between the series lower electrode 300A and the upper electrode 500A, it vibrates at the frequency of the corresponding inherent vibration, similar to the parallel resonator.

The substrate 100A is a semiconductor substrate. A silicon wafer may be typically used, and preferably, a high resistance silicon (HRS) substrate may be used. An insulating layer (not shown) may be formed on an upper surface of the substrate 100A. The insulating layer may employ a thermal oxide film that can be easily grown on the substrate 100A or may selectively employ an oxide film or nitride film formed by conventional deposition processes such as chemical vapor deposition.

The substrate 100A may include a parallel substrate portion 110A and a series substrate portion 120A constituting the parallel resonator. The parallel substrate portion 110A has a parallel cavity 112A formed on the upper part, while the series substrate portion 120A has a series cavity 122A formed on the upper part.

The parallel cavity 112A and the series cavity 122A are formed by forming cavities respectively on the parallel substrate portion 110A and the series substrate portion 120A, then forming an insulating layer on the cavities, followed by depositing a sacrificial layer on the insulating layer, etching for planarization, and then removing the sacrificial layer. Here, the sacrificial layer uses a material with excellent surface roughness such as polysilicon or ZnO, which is easy to form and remove. For example, polysilicon may be employed as the sacrificial layer, which not only has excellent surface roughness and is easy to form and remove, but can also be removed using dry etching in subsequent processes.

The parallel lower electrode 200A and the series lower electrode 300A are each formed on the upper part of the substrate 100A where the sacrificial layers exist on the cavities. The parallel lower electrode 200A and the series lower electrode 300A are formed at a predetermined distance apart from each other.

The parallel lower electrode 200A and the series lower electrode 300A are each formed by depositing a predetermined material on the upper part of the substrate 100A and patterning it. The material used for the parallel lower electrode 200A and the series lower electrode 300A is a typical conductive material such as metal, and preferably one of aluminum (Al), tungsten (W), gold (Au), platinum (Pt), nickel (Ni), titanium (Ti), chromium (Cr), palladium (Pd), and molybdenum (Mo).

The parallel lower electrode 200A is formed on the upper part of the substrate 100A where the parallel cavity 112A is formed, and is laminated to surround the parallel cavity 122A. In this case, the thickness of the parallel lower electrode 200A may be greater than or equal to 179 nm and less than or equal to 287 nm.

The series lower electrode 300A is formed on the upper part of the substrate 100A where the series cavity 122A is formed, and is laminated to surround the series cavity 122A.

The series lower electrode 300A consists of a first series lower electrode 310A and a second series lower electrode 320A.

The first series lower electrode 310A is a lower electrode formed on the portion of the series substrate portion 120A where the series cavity 122A is formed. Additionally, the second series lower electrode 320A is a lower electrode formed on the portion of the series substrate portion 120A where the series cavity 122A is not formed.

The thickness of the second series lower electrode 320A may be the same as the thickness of the parallel lower electrode 200A.

Meanwhile, the thickness of the first series lower electrode 310A may be less than or equal to a predetermined thickness compared to the thickness of the second series lower electrode 320A. For example, the thickness of the first series lower electrode 310A may be less than or equal to ⅔ of the thickness of the second series lower electrode 320A. Specifically, the thickness of the first series lower electrode 310A may be 63.2% or less of the thickness of the second series lower electrode 320A.

Therefore, at a series electrode boundary surface 311A that forms the boundary between the first series lower electrode 310A and the second series lower electrode 320A, the first series lower electrode 310A forms a height difference with the second series lower electrode 320A. Accordingly, a desired resonant frequency may be achieved by etching the first series lower electrode 310A, while an increase in surface resistance may be prevented by maintaining the second series lower electrode 320A to be thick.

Additionally, the series electrode boundary surface 311A that forms the boundary between the first series lower electrode 310A and the second series lower electrode 320A may be formed outward from a vertical imaginary surface 123A that defines the space of the series cavity 122A. In other words, the series electrode boundary surface 311A is shifted in the direction where a pad connected to the series resonator is placed, rather than being positioned on the line of the imaginary vertical surface 123A of the series cavity 122A. That is, the series electrode boundary surface 311A may be positioned at a distance of 0 to 6.3 μm away from the vertical imaginary surface 123A of the cavity.

In this case, as the series electrode boundary surface 311A becomes closer to the vertical imaginary surface 123A, a greater effect of resistance improvement may be achieved. Conversely, as the series electrode boundary surface 311A moves away from the vertical imaginary surface 123A, the effect of resistance improvement may decrease, but ease of manufacturing processes is obtained.

As a part of the first series lower electrode 310A, an electrode edge 312A adjacent to the parallel lower electrode 200A may have a thickness less than or equal to a predetermined thickness compared to the thickness of the parallel lower electrode 200A. In this case, the thickness of the electrode edge 312A may be less than or equal to ⅔ of the thickness of the second series lower electrode 320A. Specifically, the thickness of the electrode edge 312A may be 63.2% or less of the thickness of the second series lower electrode 320A.

Through structural changes to the first series lower electrode 310A according to the above-described embodiment, the resistance is reduced by approximately 16.3 to 26.6%, which may lead to an improvement effect of 0.06 to 0.10 dB for insertion loss (IL).

The piezoelectric layer 400A is formed on the parallel lower electrode 200A and the series lower electrode 300A. The piezoelectric layer 400A may be formed by depositing a piezoelectric material on the parallel lower electrode 200A and the series lower electrode 300A and patterning it afterward. Typically, materials such as aluminum nitride (AlN) or zinc oxide (ZnO) may be used as the piezoelectric material. Deposition methods such as RF magnetron sputtering and evaporation are employed.

The upper electrode 500A is formed on the piezoelectric layer 400A. The upper electrode 500A may be formed by depositing a metal film for an upper electrode on a predetermined region on the piezoelectric layer 300A and patterning it afterward. The upper electrode 500A may use the same material, deposition method, and patterning method as the parallel lower electrode 200A or the series lower electrode 300A.

Meanwhile, although not illustrated, a pad layer may be formed to apply the parallel lower electrode 200A, the series lower electrode 300A, the piezoelectric layer 400A, and a portion of the upper electrode 500A which are described above. The pad layer serves as a cover to protect the parallel lower electrode 200A, the series lower electrode 300A, the piezoelectric layer 400A, and the upper electrode 500A.

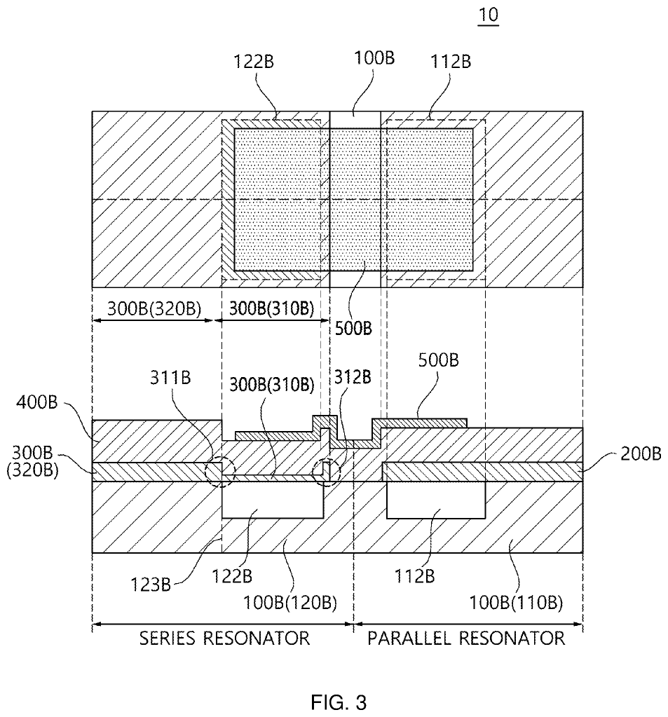

FIG. 3 shows a plan view and cross-sectional view of another embodiment of the piezoelectric thin film filter 10 shown in FIG. 1.

Referring to FIG. 3, the piezoelectric thin film filter 10 includes a substrate 100B, a parallel lower electrode 200B, a series lower electrode 300B, a piezoelectric layer 400B, and an upper electrode 500B.

Here, the characteristics of the substrate 100B, parallel lower electrode 200B, piezoelectric layer 400B, and upper electrode 500B are the same as those of the substrate 100A, parallel lower electrode 200A, piezoelectric layer 400A, and upper electrode 500A described above in FIG. 2, so detailed descriptions thereof are omitted, and the description below focuses on the series lower electrode 300B.

The series lower electrode 300B is formed on the upper part of the substrate 100B where the series cavity 122B is formed, and is laminated to surround the series cavity 122B.

The series lower electrode 300B consists of a first series lower electrode 310B and a second series lower electrode 320B.

The first series lower electrode 310B is a lower electrode formed on the portion of the series substrate portion 120B where the series cavity 122B is formed. Additionally, the second series lower electrode 320B is a lower electrode formed on the portion of the series substrate portion 120B where the series cavity 122B is not formed.

The thickness of the second series lower electrode 320B may be the same as the thickness of the parallel lower electrode 200B.

Meanwhile, the thickness of the first series lower electrode 310B may be less than or equal to a predetermined thickness compared to the thickness of the second series lower electrode 320B. For example, the thickness of the first series lower electrode 310B may be less than or equal to ⅔ of the thickness of the second series lower electrode 320B. Specifically, the thickness of the first series lower electrode 310B may be 63.2% or less of the thickness of the second series lower electrode 320B.

Accordingly, at a series electrode boundary surface 311B that forms the boundary between the first series lower electrode 310B and the second series lower electrode 320B, the first series lower electrode 310B forms a height difference with the second series lower electrode 320B.

Additionally, the series electrode boundary surface 311B that forms the boundary between the first series lower electrode 310B and the second series lower electrode 320B may be formed outward from a vertical imaginary surface 123B that defines the space of the series cavity 122B. In other words, the series electrode boundary surface 311B may be positioned on the same plane as the vertical imaginary surface 123B of the series cavity 122B.

On the other hand, as a part of the first series lower electrode 310B, an electrode edge 312B adjacent to the parallel lower electrode 200B may extend upward with respect to the substrate 100B to correspond to the thickness of the parallel lower electrode 200B. The electrode edge 312B of the first series lower electrode 310B may have a width greater than or equal to 1 nm and less than or equal to 10 nm.

The electrode edge 312B of the first series lower electrode 310B protrudes upward, and the height of this protrusion may correspond to the thickness of the parallel lower electrode 200B.

Through structural changes to the first series lower electrode 310B according to the above-described embodiment, the resistance is reduced by approximately 40.2%, which may lead to an improvement effect of approximately 0.15 dB for insertion loss (IL).

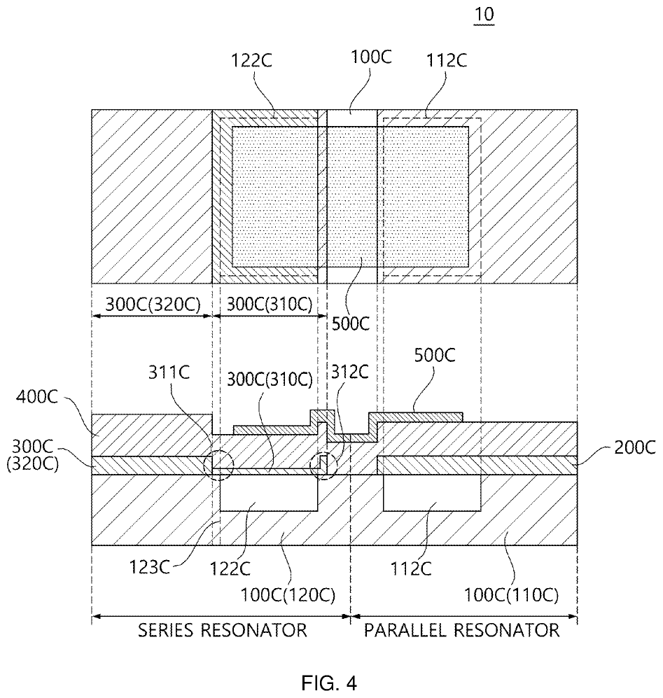

FIG. 4 shows a plan view and cross-sectional view of yet another embodiment of the piezoelectric thin film filter 10 shown in FIG. 1.

Referring to FIG. 4, the piezoelectric thin film filter 10 includes a substrate 100C, a parallel lower electrode 200C, a series lower electrode 300C, a piezoelectric layer 400C, and an upper electrode 500C.

Here, the characteristics of the substrate 100C, parallel lower electrode 200C, piezoelectric layer 400C, and upper electrode 500C are the same as those of the substrate 100A, parallel lower electrode 200A, piezoelectric layer 400A, and upper electrode 500A described above in FIG. 2, so detailed descriptions thereof are omitted, and the description below focuses on the series lower electrode 300C.

The series lower electrode 300C is formed on the upper part of the substrate 100C where the series cavity 122C is formed, and is laminated to surround the series cavity 122C.

The series lower electrode 300C consists of a first series lower electrode 310C and a second series lower electrode 320C.

The first series lower electrode 310C is a lower electrode formed on the portion of the series substrate portion 120C where the series cavity 122C is formed. Additionally, the second series lower electrode 320C is a lower electrode formed on the portion of the series substrate portion 120C where the series cavity 122C is not formed.

The thickness of the second series lower electrode 320C may be the same as the thickness of the parallel lower electrode 200C.

Meanwhile, the thickness of the first series lower electrode 310C may be less than or equal to a predetermined thickness compared to the thickness of the second series lower electrode 320C. For example, the thickness of the first series lower electrode 310C may be less than or equal to ⅔ of the thickness of the second series lower electrode 320C. Specifically, the thickness of the first series lower electrode 310C may be 63.2% or less of the thickness of the second series lower electrode 320C.

Accordingly, at a series electrode boundary surface 311C that forms the boundary between the first series lower electrode 310C and the second series lower electrode 320C, the first series lower electrode 310C forms a height difference with the second series lower electrode 320C.

Additionally, the series electrode boundary surface 311C that forms the boundary between the first series lower electrode 310C and the second series lower electrode 320C may be formed outward from a vertical imaginary surface 123C that defines the space of the series cavity 122C. That is, the series electrode boundary surface 311C is shifted a predetermined distance away from the vertical imaginary surface 123C of the series cavity 122C, rather than being positioned on the line of the vertical imaginary surface 123C. For example, the series electrode boundary surface 311C may be positioned at a distance of 0 to 6.3 μm away from the vertical imaginary surface 123C of the cavity.

On the other hand, as a part of the first series lower electrode 310C, an electrode edge 312C adjacent to the parallel lower electrode 200C may extend upward with respect to the substrate 100C to correspond to the thickness of the parallel lower electrode 200C. The electrode edge 312C of the first series lower electrode 310C may have a width greater than or equal to 1 nm and less than or equal to 10 nm.

The electrode edge 312C of the first series lower electrode 310C protrudes upward, and the height of this protrusion may correspond to the thickness of the parallel lower electrode 200C.

Through structural changes to the first series lower electrode 310C according to the above-described embodiment, the resistance is reduced by approximately 28.3 to 33.4%, which may lead to an improvement effect of 0.10 to 0.10 dB for insertion loss (IL).

The exemplary embodiments of the present invention have been described above. One of ordinary skill in the art may understand that modifications may be made without departing from the scope of the present invention. Therefore, the disclosed embodiments should be considered in a descriptive aspect not a limitative aspect. The scope of the present invention is defined by the claims not the above description, and all differences within the equal scope thereof should be interpreted as being included in the present invention.

What is claimed:

1. A piezoelectric thin film filter with a parallel resonator and a series resonator, comprising:
a substrate comprising a parallel cavity constituting the parallel resonator and a series cavity constituting the series resonator;
a parallel lower electrode formed on a parallel substrate portion constituting the parallel resonator in the substrate;
a series lower electrode formed on a series substrate portion constituting the series resonator in the substrate;
a piezoelectric layer formed on the substrate, the parallel lower electrode, and the series lower electrode; and
an upper electrode formed on the piezoelectric layer,
wherein the series lower electrode comprises a first series lower electrode formed on a portion where the series cavity is formed in the series substrate portion, and a second series lower electrode formed on a portion where the series cavity is not formed in the series substrate portion,
wherein a thickness of the first series lower electrode is less than or equal to a predetermined thickness compared to a thickness of the second series lower electrode.

2. The piezoelectric thin film filter of claim 1, wherein the thickness of the first series lower electrode is less than or equal to ⅔ of the thickness of the second series lower electrode.

3. The piezoelectric thin film filter of claim 1, wherein the thickness of the second series lower electrode is the same as a thickness of the parallel lower electrode.

4. The piezoelectric thin film filter of claim 1, wherein an electrode edge, a part of the first series lower electrode, adjacent to the parallel lower electrode extends upward to correspond to a thickness of the parallel lower electrode.

5. The piezoelectric thin film filter of claim 4, wherein the electrode edge has a width greater than or equal to 1 nm and less than or equal to 10 nm.

6. The piezoelectric thin film filter of claim 1, wherein an electrode edge, a part of the first series lower electrode, adjacent to the parallel lower electrode is a predetermined thickness or less compared to the thickness of the parallel lower electrode.

7. The piezoelectric thin film filter of claim 1, wherein a series electrode boundary surface of the first series lower electrode that forms a boundary with the second series lower electrode is formed at a position corresponding to a vertical imaginary surface that defines a space of the series cavity.

8. The piezoelectric thin film filter of claim 1, wherein a series electrode boundary surface of the first series lower electrode that forms a boundary with the second series lower electrode is formed outward from a vertical imaginary surface that defines a space of the series cavity.
